(19) United States
(12) Patent Application Publication
(10) Pub. No.: US 2026/0173250 A1
(43) Pub. Date: Jun. 18, 2026

(54) OPTIMIZATION OF TAPER ROUTING FOR HIGH-SPEED SIGNALING

(71) Applicant: Infineon Technologies Americas Corp., EI Segundo, CA (US)

(72) Inventors: Shaowu HUANG, Los Altos, CA (US); Hon Wai FUNG, Newark, CA (US)

(73) Assignee: Infineon Technologies Americas Corp., EI Segundo, CA (US)

(21) Appl. No.: 19/396,496

(22) Filed: Nov. 21, 2025

Related U.S. Application Data
(60) Provisional application No. 63/735,016, filed on Dec. 17, 2024.

(51) Int. Cl. H05K 1/02; H05K 1/11; H05K 1/18; H05K 3/40

(52) U.S. Cl. CPC H05K 1/0237; H05K 1/115; H05K 1/18; H05K 3/4038; H05K 2201/09009

(57) ABSTRACT

A system and method of mitigating impedance mismatches in high-speed electronic systems. The method includes providing a first uniform conductive region electrically coupled to a first electronic component associated with a first impedance. The method includes providing a second uniform conductive region electrically coupled to a second electronic component associated with a second impedance. The method includes forming a non-uniform conductive region between the first uniform conductive region and the second uniform conductive region, the non-uniform conductive region having a geometry that varies along a longitudinal direction to form a taper that is configured to produce a spatially varying characteristic impedance along the non-uniform conductive region.

### CROSS-REFERENCE TO RELATED APPLICATIONS

This application claims the benefit of U.S. Provisional Application Ser. No. 63/735,016 entitled “Optimization of Taper Routing for High-Speed Signaling,” filed Dec. 17, 2024, the disclosure of which is incorporated herein by reference in its entirety.

### TECHNICAL FIELD

The present disclosure relates generally to the field of high-speed electronic interconnects, and more particularly, to systems and methods for mitigating impedance mismatches in high-speed electronic systems using taper routing techniques implemented within printed circuit boards (PCBs) and semiconductor packages.

### BACKGROUND

In high-speed electronic systems, signal transmission quality is heavily influenced by the impedance characteristics of the transmission path. Each segment of the signal path, whether in a printed circuit board, package substrate, connector, or cable, has a characteristic impedance that ideally should match the impedance of the transmitter and receiver. When there is a mismatch between these impedances, part of the signal energy is reflected back toward the source, resulting in signal degradation, increased return loss, and potential data errors. These reflections can distort the signal waveform, reduce timing margins, and include overall system reliability. To ensure maximum power transfer and maintain signal integrity, it is desirable to achieve a continuous impedance profile throughout the signal path, minimizing discontinuities that lead to reflections.

### BRIEF DESCRIPTION OF THE DRAWINGS

The present disclosure is illustrated by way of example, and not by way of limitation, in the figures of the accompanying drawings in which like reference numerals refer to similar elements and in which:

FIG. 1 illustrates an example high-speed electronic system including a high-impedance differential transmitter and a low-impedance differential receiver that communicate using a tapered PCB trace consisting of a single tapered region, in accordance with some embodiments;

FIG. 2 illustrates an example high-speed electronic system that includes a high-impedance differential transmitter and a low-impedance differential receiver coupled through PCB vias and a tapered PCB trace, in accordance with some embodiments;

FIG. 3 illustrates an example high-speed electronic system that includes a high-impedance differential transmitter and a low-impedance differential receiver coupled through PCB vias and a tapered PCB trace, in accordance with some embodiments;

FIG. 4 illustrates an example high-speed electronic system including a high-impedance differential transmitter and a low-impedance differential receiver communicating through a tapered PCB trace that incorporates an outside bending region, in accordance with some embodiments;

FIG. 5 illustrates an example high-speed electronic system including a high-impedance differential transmitter and a low-impedance differential receiver communicating through a tapered PCB trace that incorporates an inside bending region, in accordance with some embodiments;

FIG. 6 illustrates an example high-speed electronic system including a high-impedance differential transmitter and a low-impedance differential receiver communicating through a tapered PCB trace consisting of multiple tapered regions, in accordance with some embodiments;

FIG. 7A illustrates an example of tapered routing applied in one direction, in accordance with some embodiments;

FIG. 7B illustrates an example of an alternative tapered routing applied in one direction, in accordance with some embodiments;

FIG. 7C illustrates an example of tapered routing applied in both directions, in accordance with some embodiments;

FIG. 8A illustrates an example of improved routing without tapered regions, in accordance with some embodiments;

FIG. 8B illustrates an example of improved routing without tapered regions, in accordance with some embodiments;

FIG. 9 illustrates an example semiconductor package configured to resolve impedance matching between wirebonds and PCB, in accordance with some embodiments;

FIG. 10 illustrates an example semiconductor package configured to resolve impedance matching between wirebonds and PCB, in accordance with some embodiments;

FIG. 11 is a flow diagram of a method of mitigating impedance mismatches in high-speed electronic systems using taper routing techniques implemented within PCBs and semiconductor packages; and

FIG. 12 is a block diagram of an example computing device that may perform one or more of the operations described herein, in accordance with some embodiments.

### DETAILED DESCRIPTION

The following description sets forth numerous specific details such as examples of specific systems, components, methods, and so forth, in order to provide a good understanding of various embodiments of the techniques described herein for mitigating impedance mismatches in high-speed electronic systems using taper routing techniques implemented within printed circuit boards (PCBs) and semiconductor packages. It will be apparent to one skilled in the art, however, that at least some embodiments may be practiced without these specific details. In other instances, well-known components, elements, or methods are not described in detail or are presented in a simple block diagram format to avoid unnecessarily obscuring the techniques described herein. Thus, the specific details set forth hereinafter are merely exemplary. Particular implementations may vary from these exemplary details and still be contemplated to be within the scope of the present disclosure.

In high-speed signal interfaces, impedance mismatches between the transmitter (TX) and receiver (RX) can significantly degrade signal integrity. This issue is particularly prevalent in automotive systems, where a serializer-deserializer (SerDes) interface may connect a networking system-on-chip (SoC), such as an automotive switch SoC, to a computing SoC, such as an automotive graphics processing unit (GPU) SoC. These SoCs are often sourced from different vendors, and their SerDes input/output (I/O) ports may exhibit differing differential impedances. For example, a SerDes port on the switch SoC may have a characteristic impedance of 100 ohms, while the corresponding port on the GPU SoC may have an impedance of 85 ohms. Such mismatches can result in increased return loss, degraded signal performance, and potential link failures.

In some automotive platform designs, 10 gigabit per second serializer-deserializer (SerDes) links may connect GPU SoCs that conform to the Small Form Factor (SFF) Committee INF-8077i specification, titled “10 Gigabit Small Form Factor Pluggable (XFP) Module Specification”, which specifies an 85-ohm differential impedance. These links may interface with switch SoCs that conform to the IEEE 802.3-2018 KR specification, formally known as “10GBASE-KR: IEEE 802.3 Physical Layer Specification for 10 Gb/s over Backplane”, which specifies a 100-ohm differential impedance. This impedance mismatch between the SerDes ports of the GPU SoC and the switch SoC reduces the operational margin of the SerDes link, adversely affecting the eye diagram and overall signal integrity.

Impedance mismatches are not limited to chip-to-chip interfaces. They also occur along PCB traces due to the presence of components such as alternating current (AC) coupling capacitors, which are used to block direct current (DC) while allowing high-speed AC signals to pass between devices. Other contributors to impedance discontinuities include common mode chokes (CMCs) and cable connectors. Additionally, mismatches may arise within semiconductor packages due to wirebond structures and ball grid array (BGA) pin field routing, which inherently introduce higher impedance. These discontinuities contribute to return loss and further degrade performance in high-speed SerDes and Ethernet channels.

Accordingly, there is a long-felt need for improved techniques that compensate for or mitigate impedance mismatches in high-speed signal interfaces.

Aspects of the present disclosure provide routing techniques that replace conventional uniform trace routing with taper routing that mitigate impedance mismatches in high-speed electronic systems, including those implemented within PCBs and semiconductor packages. For example, taper routing may be used to address impedance mismatches in automotive Ethernet systems, where differences in differential impedance between components can degrade signal quality.

The taper routing techniques described herein are applicable at both the printed circuit board level. For example, they may be used to match impedances across components such as alternating current coupling capacitors, common mode chokes, common mode termination structures, and connectors. These techniques are also applicable at the semiconductor package level, where impedance mismatches may result from wirebond structures or ball grid array pin field routing.

Taper routing may be implemented using a variety of taper geometries, including linear, piecewise, polynomial, exponential, and Klopfenstein profiles. These techniques are suitable for both differential signal interfaces and single-ended signal interfaces, providing a flexible and scalable solution for improving signal quality in high-speed electronic systems.

Example applications include memory systems, automotive Ethernet systems (used for in-vehicle networking), Fibre Channel networks (used in storage area networks), Synchronous Optical Networking or SONET-based communication systems (used in telecommunications infrastructure), Peripheral Component Interconnect Express or PCI Express interfaces (used for high-speed data transfer in computing systems), and high performance computing platforms, among others.

This approach significantly improves signal integrity, particularly return loss, in high-speed interfaces such as SerDes and Ethernet. It achieves these enhancements without introducing additional cost or increasing power consumption. Furthermore, it does not negatively affect insertion loss and has only negligible impact on other electrical performance metrics, including mode conversion.

In an illustrative embodiment, a signal routing system includes a first uniform conductive region electrically coupled to a first electronic component associated with a first impedance. The signal routing system includes a second uniform conductive region electrically coupled to a second electronic component associated with a second impedance. The signal routing system includes a non-uniform conductive region disposed between the first uniform conductive region and the second uniform conductive region, the non-uniform conductive region having a geometry that varies along a longitudinal direction to form a taper that is configured to produce a spatially varying characteristic impedance along the non-uniform conductive region.

As discussed in further detail below, various implementations of PCB traces are configured to compensate for or mitigate impedance mismatches in high-speed signal interfaces. A PCB trace may be disposed on a top layer of a PCB (sometimes referred to herein as the PCB board) or within any internal layer of the PCB. For example, a PCB may include, from top to bottom: a silkscreen layer for component labeling; a solder mask layer for protecting copper traces; a top copper layer for signal routing and component mounting; one or more dielectric layers for electrical insulation and mechanical support; internal copper layers for power and ground distribution (in multilayer configurations); additional internal copper layers for internal signal routing; a bottom copper layer; and corresponding bottom solder mask and silkscreen layers.

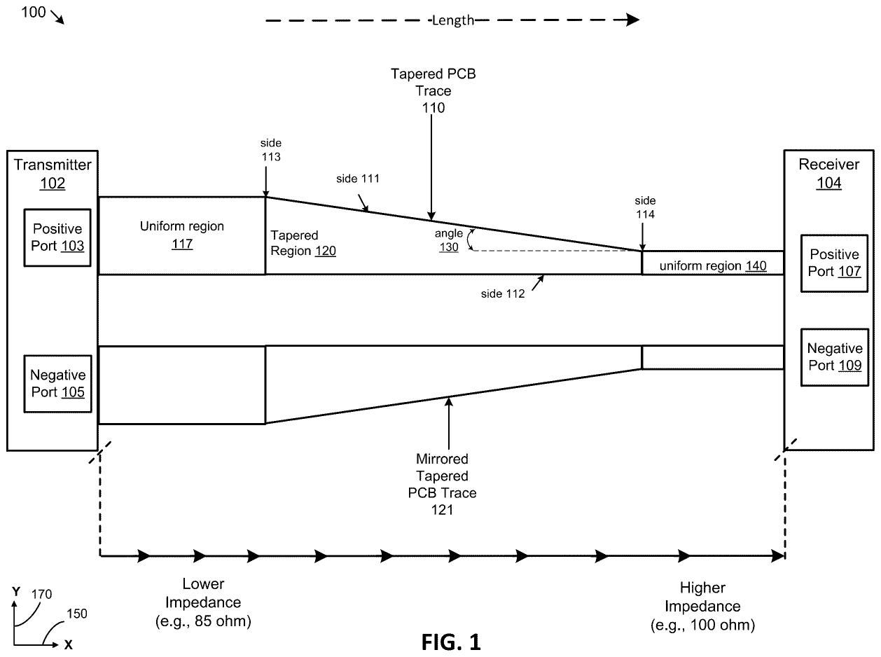

FIG. 1 illustrates an example high-speed electronic system including a high-impedance differential transmitter and a low-impedance differential receiver that communicate using a tapered PCB trace consisting of a single tapered region, in accordance with some embodiments.

The high-speed electronic system 100a includes a transmitter 102, implemented as an integrated circuit (IC) device, and a receiver 104, which is also an IC device. The transmitter 102 includes a differential output interface consisting of a positive port 103 and a negative port 105. The receiver 104 includes a differential input interface consisting of a positive port 107 and a negative port 109. The differential output impedance of the transmitter 102 is greater than the differential input impedance of the receiver 104.

As shown in FIG. 1, the differential output interface has an impedance of 100 ohms, while the differential input interface has an impedance of 85 ohms. However, other embodiments may exhibit different impedance mismatches. In such embodiments, each of the differential output interface and the differential input interface may have an impedance fixed at a value between 50 ohms and 100 ohms, provided that the output impedance remains greater than the input impedance.

The PCB trace 110 includes a uniform region 110, a tapered region 120, and a uniform region 140. The positive port 107 of the receiver 104 is electrically coupled to the positive port 107 of the receiver 104 via these regions. Specifically, the positive port 103 of the transmitter 102 is electrically coupled to the uniform region 117, which connects to the tapered region 120 via side 113. The tapered region 120 connects to uniform region 140 via side 114, which in turn is electrically coupled to the positive port 107 of the receiver 104.

The tapered region 120 is a closed geometric shape including four sides: side 111 having a first length, side 112 having a second length, side 113 having a third length, and side 114 having a fourth length.

Each of the four sides has a different length. For example, side 114 is shorter than side 113, which is shorter than side 112, which is shorter than side 111. Side 113 and side 114 extend vertically along the y-axis 170 and are parallel (or substantially parallel) to one another. Side 112 extends horizontally along the x-axis 150 between side 113 and side 114, defining the total length of the tapered region 120 in the x-direction (as shown in FIG. 1). Side 111 also extends between side 113 and side 114. Together, these four sides define the closed geometric shape of the tapered PCB trace 110.

As discussed herein, impedance mismatches along a signal path can lead to increased signal reflections and degraded signal integrity. To mitigate the impedance mismatch resulting from the differential output interface of transmitter 102 having a higher impedance than the differential input interface of receiver 104, side 111 of tapered PCB trace 110 is configured to be tapered. Specifically, side 111 slopes in the negative direction along the y-axis 170 as it extends from its connection with side 113 to its termination at side 114. Angle 130 is formed between side 111 and an imaginary horizontal line parallel to the x-axis 150 and originating at side 114.

The negative port 105 of the transmitter 102 is electrically coupled to the negative port 109 of the receiver 104 via a mirrored tapered PCB trace 121. The mirrored PCB trace 121 is identical in shape and electrical performance to PCB trace 110, but is vertically flipped relative to PCB trace 110.

### Design Rules for Taper Routing Length

The length of a taper routing segment (e.g., tapered region 120) can be determined based on the required bandwidth of high-speed signaling. The taper length establishes a corresponding cut-off frequency, which in turn determines the effective bandwidth. The cut-off frequency is defined as the lowest frequency at which the taper routing effectively reduces return loss, thereby minimizing signal reflection, by a specified magnitude such as 3 decibel (dB), 5 dB, or 10 dB.

Simulation results for a typical PCB and package substrate with a dielectric constant of approximately 4 indicate that the cut-off frequency varies with taper length. For example, the 5 dB cut-off frequency of taper routing is approximately 0.2 gigahertz (GHz) for a taper length of 1.5 inches, 1.5 GHz for 1 inch, 2.5 GHz for 0.5 inch, 3 GHz for 0.3 inch, and 5 GHz for 0.2 inch. Similarly, the 10 dB cut-off frequency is approximately 1.5 GHz for 1.5 inches, 2.5 GHz for 1 inch, 5 GHz for 0.5 inch, 6.5 GHz for 0.3 inch, and 8.5 GHz for 0.2 inch.

Accordingly, the taper routing length should be selected based on the data rate and bandwidth requirements of the high-speed interface. For interfaces operating at lower data rates, in some embodiments, a relatively longer taper routing is preferred because it provides a lower cut-off frequency and improves return loss across a broader frequency range. Conversely, interfaces with higher data rates typically have a larger in-band bandwidth, allowing for a higher cut-off frequency and therefore a shorter taper routing length.

### Slope Requirement of PCB Taper Routing

The slope of a PCB taper routing segment typically ranges from approximately 0.08 degrees to 0.7 degrees. For high-speed interfaces, the trace width of PCB routing is generally between 6 mils and 12 mils. To achieve impedance matching in high-speed interconnects, the PCB trace width must be tapered by about 20% to 50%, which corresponds to a width reduction of approximately 1.5 mils to 6 mils, depending on the PCB stack-up. Because the taper routing length must be at least 0.2 inches to 1 inch, depending on the signal data rate and bandwidth, the resulting slope can be very small. For example, a taper width change of 1.5 mils over a length of 1 inch corresponds to a slope of atan(1.5 mil/1 inch), or approximately 0.086 degrees, where atan refers to arc tangent.

As an example, for impedance matching between 85 ohms and 100 ohms, where the trace width changes from 9 mils to 6.5 mils, the taper slope is approximately 0.14 degrees for a taper length of 1 inch, 0.28 degrees for 0.5 inch, and 0.72 degrees for 0.2 inch.

### Slope Requirement of Package Substrate Taper Routing

The slope of a package substrate taper routing segment typically ranges from approximately 0.05 degrees to 0.5 degrees. For high-speed I/O interfaces, the trace width on a package substrate is generally between 30 micrometers and 80 micrometers. To achieve impedance matching in high-speed interconnects, the trace width must be tapered by about 20% to 50%, which corresponds to a width reduction of approximately 10 micrometers to 40 micrometers, depending on the substrate stack-up. Because the taper routing length must be at least 2.5 millimeters to 12.5 millimeters (0.1 inch to 0.5 inch), depending on the signal data rate and bandwidth, the slope can be very small. For example, a taper width change of 10 micrometers over a length of 12.5 millimeters corresponds to a slope of atan(10 μm/12.5 mm), or approximately 0.046 degrees.

As an example, to compensate for a differential impedance mismatch between a PCB trace and a wire bond, where the impedance changes from 100 ohms to 150 ohms, the differential trace width on the substrate must taper from 45 micrometers (100 ohms) to 20 micrometers (150 ohms). In this case, the taper slope is approximately 0.57 degrees for a taper length of 2.5 millimeters, 0.29 degrees for 5 millimeters, and 0.14 degrees for 10 millimeters.

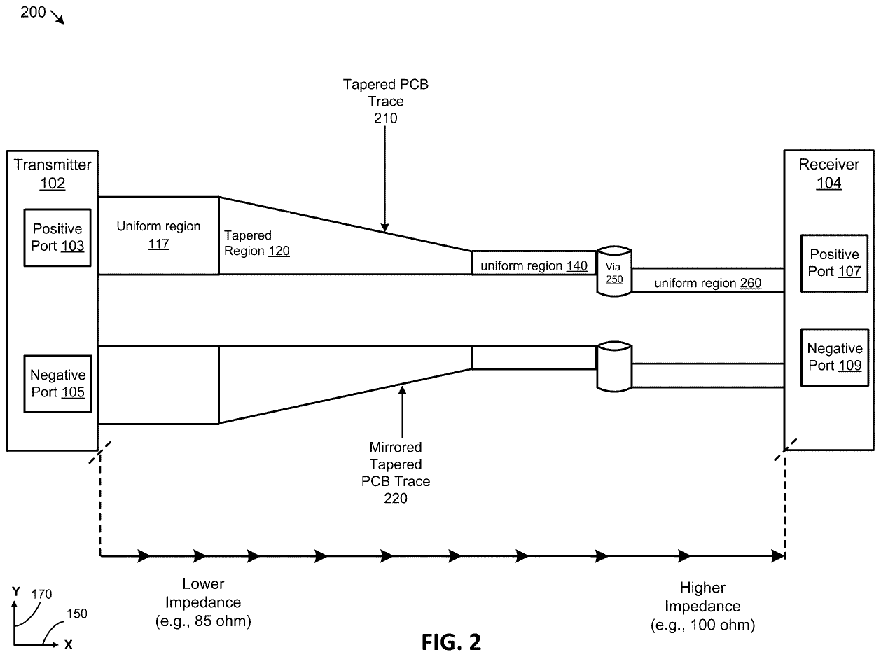

FIG. 2 illustrates an example high-speed electronic system that includes a high-impedance differential transmitter and a low-impedance differential receiver coupled through PCB vias and a tapered PCB trace, in accordance with some embodiments. In this embodiment, the vias are positioned outside the taper routing region. Positioning the vias outside the taper routing region helps prevent signal integrity degradation that could otherwise result from mode conversion or skew introduced by the taper geometry. By placing the vias outside the tapered section, the design maintains consistent impedance characteristics and reduces unwanted reflections and timing mismatches.

The high-speed electronic system 200 includes the transmitter 102 and the receiver 104 in FIG. 1, where the output interface of the transmitter 102 has a differential output impedance that is greater than the differential input impedance of the input interface of the receiver 104.

The high-speed electronic system 200 includes a tapered PCB trace 210 having the same regions as the tapered PCB 110 in FIG. 1, specifically uniform region 117, tapered region 120, and uniform region 140.

However, unlike the configuration in FIG. 1, the uniform region 140 of the tapered PCB trace 210 is electrically coupled to a via 250. The tapered PCB trace 210 also includes an additional uniform region (uniform region 260) that electrically couples via 250 to the positive port 107 of the receiver 104.

The negative port 105 of the transmitter 102 is electrically coupled to the negative port 109 of the receiver 104 via a mirrored tapered PCB trace 220. The mirrored tapered PCB trace 220 is identical in shape and electrical performance to tapered PCB trace 210, but is vertically flipped relative to tapered PCB trace 210.

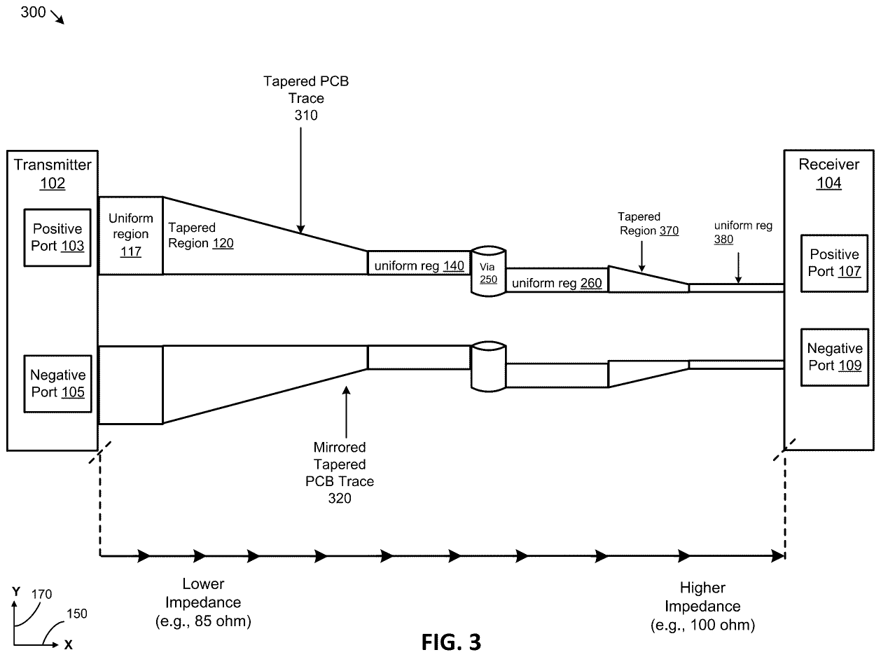

FIG. 3 illustrates an example high-speed electronic system that includes a high-impedance differential transmitter and a low-impedance differential receiver coupled through PCB vias and a tapered PCB trace, in accordance with some embodiments. In this embodiment, the vias are positioned inside the taper routing region. Co-optimizing taper routing with vias located inside the taper region can potentially provide superior signal integrity, particularly with respect to return loss performance.

The high-speed electronic system 300 includes the transmitter 102 and the receiver 104 in FIG. 1, where the output interface of the transmitter 102 has a differential output impedance that is greater than the differential input impedance of the input interface of the receiver 104.

The high-speed electronic system 300 includes a tapered PCB trace 310 having the same regions as the tapered PCB 210 in FIG. 2, specifically uniform region 117, tapered region 120, uniform region 140, via 250, and uniform region 260.

However, unlike the configuration in FIG. 2, the uniform region 260 of the tapered PCB trace 310 is electrically coupled to an additional tapered region (tapered region 370). The tapered PCB trace 310 also includes an additional uniform region (uniform region 380) that electrically couples tapered region 370 to the positive port 107 of the receiver 104.

The negative port 105 of the transmitter 102 is electrically coupled to the negative port 109 of the receiver 104 via a mirrored tapered PCB trace 320. The mirrored tapered PCB trace 320 is identical in shape and electrical performance to tapered PCB trace 310, but is vertically flipped relative to tapered PCB trace 310.

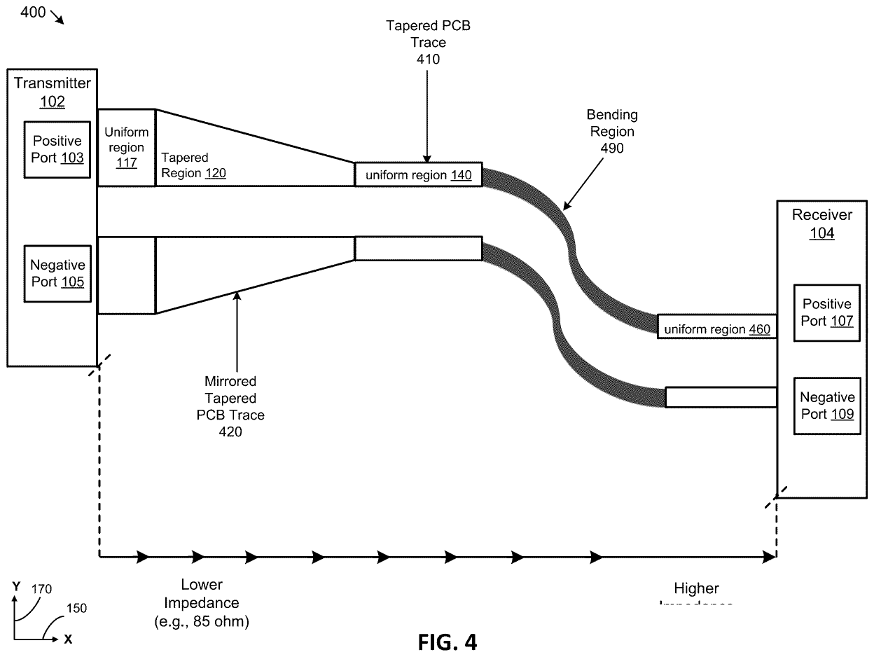

FIG. 4 illustrates an example high-speed electronic system including a high-impedance differential transmitter and a low-impedance differential receiver communicating through a tapered PCB trace that incorporates an outside bending region, in accordance with some embodiments. In this embodiment, any bending of the PCB trace is positioned outside the taper routing region. Positioning bends outside the tapered section helps prevent signal degradation that may result from mode conversion or skew introduced by the taper geometry. By maintaining straight routing within the taper region, the design preserves impedance uniformity and minimizes unwanted reflections or timing mismatches.

The high-speed electronic system 400 includes the transmitter 102 and the receiver 104 in FIG. 1, where the output interface of the transmitter 102 has a differential output impedance that is greater than the differential input impedance of the input interface of the receiver 104.

The high-speed electronic system 400 includes a tapered PCB trace 410 having the same regions as the tapered PCB 110 in FIG. 1, specifically uniform region 117, tapered region 120, and uniform region 140.

However, unlike the configuration in FIG. 1, the uniform region 140 of the tapered PCB trace 410 is electrically coupled to a bending region 490. The tapered PCB trace 410 also includes an additional uniform region (uniform region 460) that electrically couples bending region 490 to the positive port 107 of the receiver 104.

The negative port 105 of the transmitter 102 is electrically coupled to the negative port 109 of the receiver 104 via a mirrored tapered PCB trace 420. The mirrored tapered PCB trace 420 is identical in shape and electrical performance to tapered PCB trace 410, but is vertically flipped relative to tapered PCB trace 410.

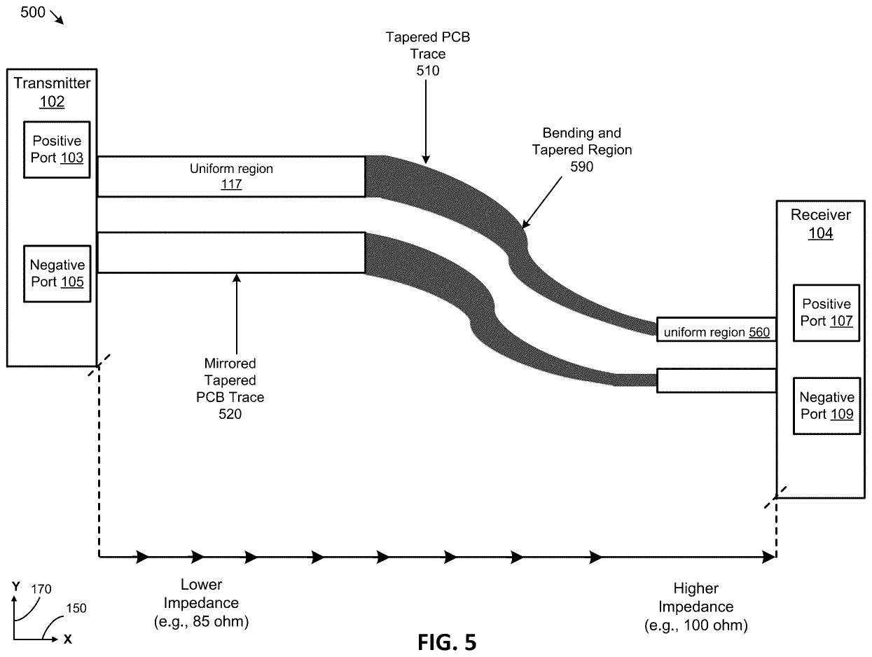

FIG. 5 illustrates an example high-speed electronic system including a high-impedance differential transmitter and a low-impedance differential receiver communicating through a tapered PCB trace that incorporates an inside bending region, in accordance with some embodiments. In this embodiment, the bending of the PCB trace occurs inside, or along, the taper routing region. Theoretically, the skew introduced by bending remains the same whether the bend is inside or outside the taper region. However, when bending is placed within the taper routing, the taper shape may might benefit from additional optimization to prevent potential degradation in signal integrity caused by mode conversion. Appropriate design adjustments ensure that the benefits of taper routing are maintained while accommodating the bend within the tapered section.

The high-speed electronic system 500 includes the transmitter 102 and the receiver 104 in FIG. 1, where the output interface of the transmitter 102 has a differential output impedance that is greater than the differential input impedance of the input interface of the receiver 104.

The high-speed electronic system 500 includes a tapered PCB trace 510 consisting of a uniform region 117, a bending and tapered region 590, and a uniform region 590. Specifically, the uniform region 117 is electrically coupled to the bending and tapered region 590, which is a region incorporating both bending and tapering to mitigate impedance mismatches. The bending and tapered region 590 is electrically coupled to the uniform region 560, which in turn is electrically coupled to the positive port 107 of the receiver 104.

The negative port 105 of the transmitter 102 is electrically coupled to the negative port 109 of the receiver 104 via a mirrored tapered PCB trace 520. The mirrored tapered PCB trace 520 is identical in shape and electrical performance to tapered PCB trace 510, but is vertically flipped relative to tapered PCB trace 510.

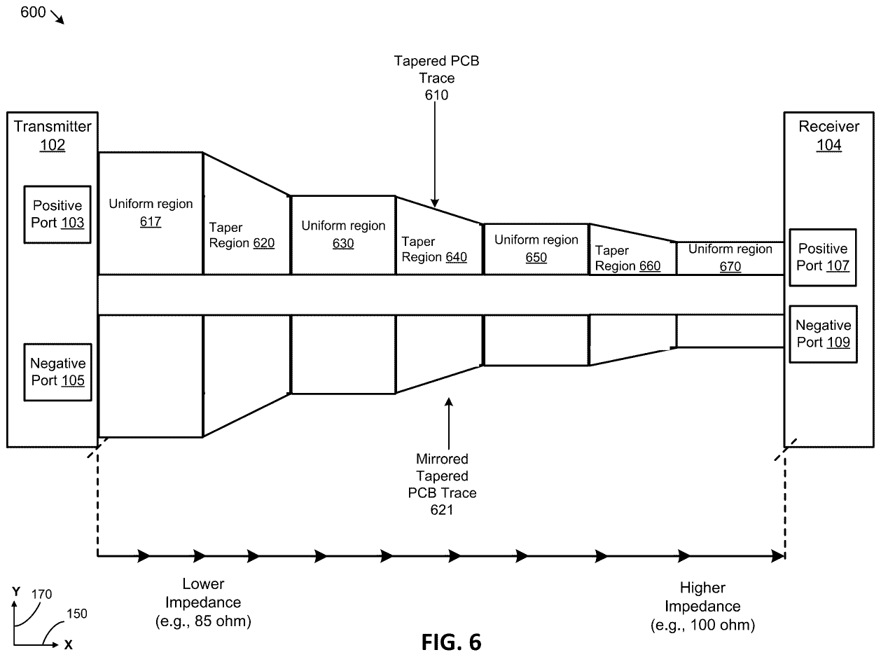

FIG. 6 illustrates an example high-speed electronic system including a high-impedance differential transmitter and a low-impedance differential receiver communicating through a tapered PCB trace consisting of multiple tapered regions, in accordance with some embodiments. In certain cases, implementing a single tapered region with sufficient length to achieve the required bandwidth may be challenging. In such situations, multiple tapered regions can be used instead of a single region. Co-optimizing multiple tapered regions can improve signal integrity, including enhanced return loss performance. However, this approach introduces a trade-off in the form of increased design complexity, as optimizing multiple regions involves more careful analysis and adjustment.

The high-speed electronic system 600 includes the transmitter 102 and the receiver 104 in FIG. 1, where the output interface of the transmitter 102 has a differential output impedance that is greater than the differential input impedance of the input interface of the receiver 104.

The high-speed electronic system 500 includes a tapered PCB trace 610 consisting of multiple uniform regions and multiple tapered regions. Specifically, uniform region 617 is electrically coupled to tapered region 620, which is electrically coupled to uniform region 630. Uniform region 630 is electrically coupled to tapered region 640, which is electrically coupled to uniform region 650. Uniform region 650 is electrically coupled to tapered region 660, which is electrically coupled to uniform region 670. Finally, uniform region 670 is electrically coupled to the positive port 107 of the receiver 104.

The negative port 105 of the transmitter 102 is electrically coupled to the negative port 109 of the receiver 104 via a mirrored tapered PCB trace 621. The mirrored tapered PCB trace 621 is identical in shape and electrical performance to tapered PCB trace 610, but is vertically flipped relative to tapered PCB trace 610.

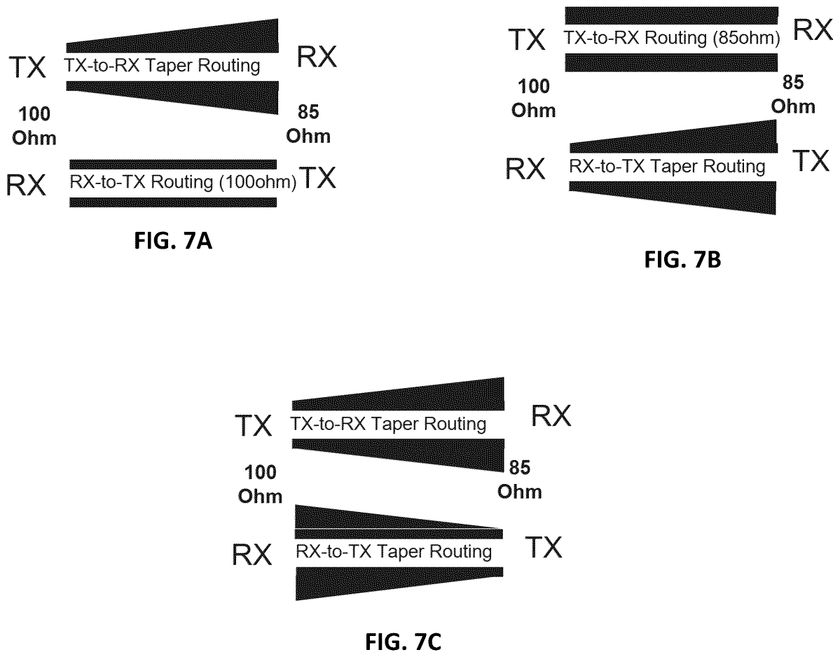

FIG. 7A illustrates an example of tapered routing applied in one direction, in accordance with some embodiments. In this embodiment, taper routing is applied only in the TX-to-RX direction, while the RX-to-TX direction uses a fixed impedance trace. This configuration partially mitigates the impedance mismatch between the transmitter (100 Ω) and the receiver (85 Ω) for one signal path, thereby improving signal integrity in that direction.

FIG. 7B illustrates an example of an alternative tapered routing applied in one direction, in accordance with some embodiments. Similar to FIG. 7A, taper routing is applied in only one direction; however, in this embodiment, the taper is used for RX-to-TX routing instead of TX-to-RX. This approach provides flexibility depending on which signal path is more critical for performance.

FIG. 7C illustrates an example of tapered routing applied in both directions, in accordance with some embodiments. In this embodiment, taper routing is applied in both the TX-to-RX and RX-to-TX directions. This co-optimized approach offers improved signal integrity and return loss performance for bidirectional communication, but it introduces higher design complexity compared to the embodiments shown in FIGS. 7A and 7B.

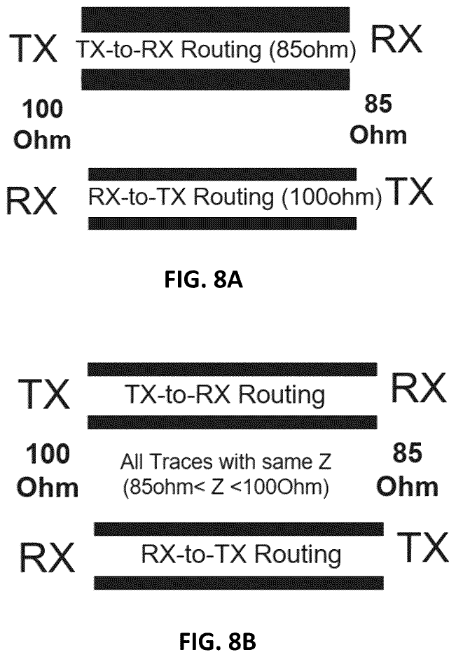

FIG. 8A illustrates an example of improved routing without tapered regions, in accordance with some embodiments. In this embodiment, the TX-to-RX and RX-to-TX signal paths use different fixed impedances rather than the same value. Specifically, the TX-to-RX path is routed at 85 Ω to match the receiver impedance, while the RX-to-TX path remains at 100 Ω. This configuration improves return loss at the receiver side, which is more critical for SerDes signal integrity, even without taper routing.

FIG. 8B illustrates an example of improved routing without tapered regions, in accordance with some embodiments. In this embodiment, both the TX-to-RX and RX-to-TX paths use the same optimized impedance value between 85 Ω and 100 Ω (e.g., 90 Ω). This compromise reduces impedance mismatch for both directions, providing balanced signal integrity without taper routing, although it does not fully optimize either path individually.

Any of the configurations depicted in FIGS. 7A-7C and 8A-8B may be used in conjunction with any of the embodiments depicted in FIGS. 1-6.

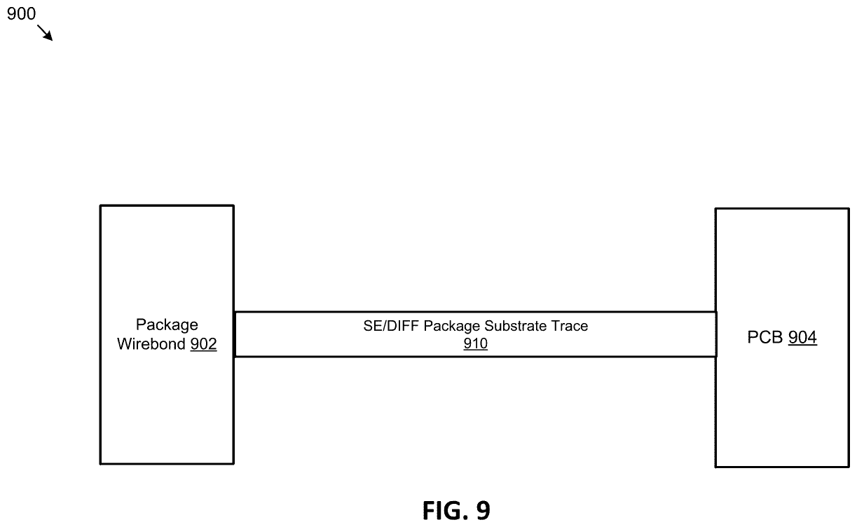

FIG. 9 illustrates an example semiconductor package configured to resolve impedance matching between wirebonds and PCB, in accordance with some embodiments. As shown in FIG. 9, a package wirebond 902 of the semiconductor package 900 may be electrically coupled to PCB 904 via single-ended or differential (SE/DIFF) package substrate trace 910, which is configured to mitigate impedance mismatches between the package wirebond 902 and the PCB 904. The semiconductor package 900 includes multiple package wirebonds 902 that are connected to various locations on the PCB 904.

In some embodiments, the SE/DIFF package substrate trace 910 may be implemented using any of the various PCB trace configurations disclosed in FIGS. 1 through 8 (8A/8B).

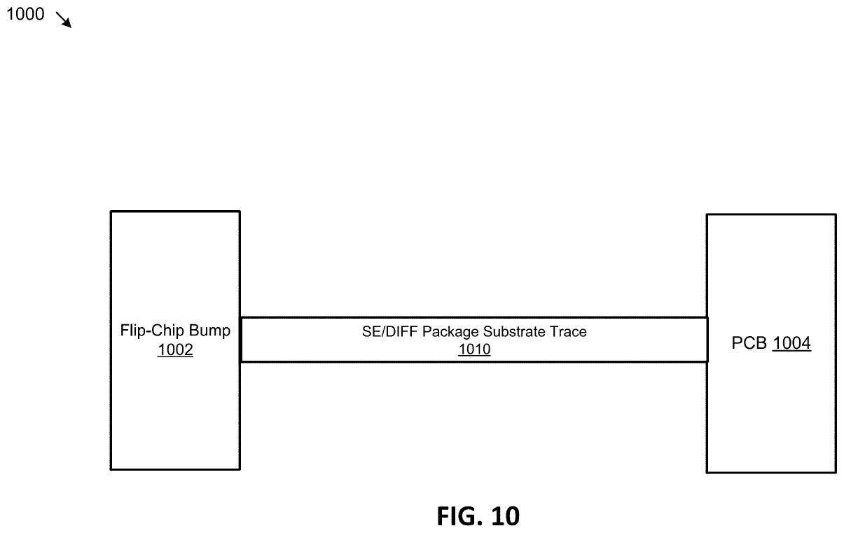

FIG. 10 illustrates an example semiconductor package configured to resolve impedance matching between wirebonds and PCB, in accordance with some embodiments. As shown in FIG. 10, a flip-chip bump 1002 of the semiconductor package 1000 may be electrically coupled to PCB 1004 via single-ended or differential (SE/DIFF) package substrate trace 1010, which is configured to mitigate impedance mismatches between the flip-chip bump 1002 and the PCB 1004. The semiconductor package 1000 includes multiple package substrate trace 1010 that are connected to various locations on the PCB 1004, such as via a ball gate array (BGA).

In some embodiments, the SE/DIFF package substrate trace 1010 may be implemented using any of the various PCB trace configurations disclosed in FIGS. 1 through 8 (8A/8B).

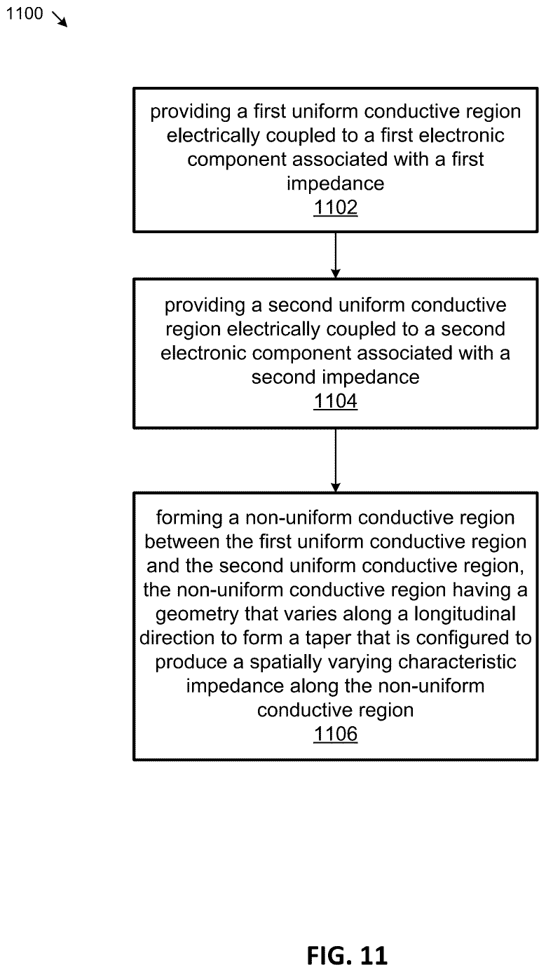

FIG. 11 is a flow diagram of a method of mitigating impedance mismatches in high-speed electronic systems using taper routing techniques implemented within PCBs and semiconductor packages. Although the operations are depicted in FIG. 11 as integral operations in a particular order for purposes of illustration, in other implementations, one or more operations, or portions thereof, are performed in a different order, or overlapping in time, in series or parallel, or are omitted, or one or more additional operations are added, or the method is changed in some combination of ways. In some embodiments, the method 1100 may be performed by processing logic that includes hardware (e.g., circuitry, dedicated logic, programmable logic, microcode, etc.), firmware, or a combination thereof. In some embodiments, some or all operations of method 1100 may be performed using semiconductor manufacturing equipment.

As shown in FIG. 11, the method 1100 includes the operation 1102 of providing a first uniform conductive region electrically coupled to a first electronic component associated with a first impedance. The method 1100 includes the operation 1104 of providing a second uniform conductive region electrically coupled to a second electronic component associated with a second impedance. The method 1100 includes the operation 1106 of forming a non-uniform conductive region between the first uniform conductive region and the second uniform conductive region, the non-uniform conductive region having a geometry that varies along a longitudinal direction to form a taper that is configured to produce a spatially varying characteristic impedance along the non-uniform conductive region.

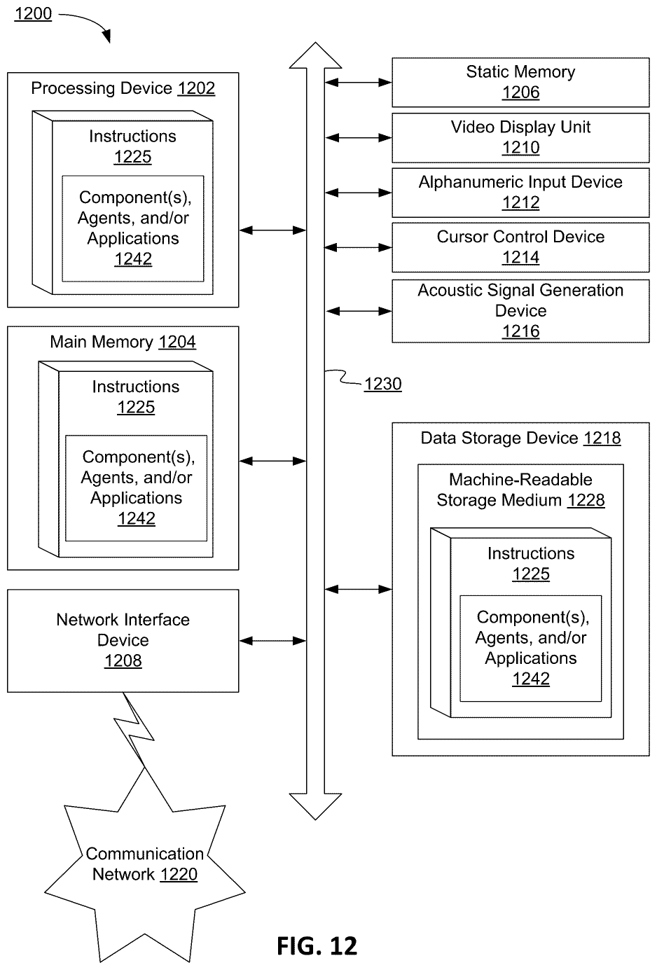

FIG. 12 is a block diagram of an example computing device that may perform one or more of the operations described herein, in accordance with some embodiments. Computing device 1200 may be connected to other computing devices in a LAN, an intranet, an extranet, and/or the Internet. The computing device may operate in the capacity of a server machine in client-server network environment or in the capacity of a client in a peer-to-peer network environment. The computing device may be provided by a personal computer (PC), a set-top box (STB), a server, a network router, switch or bridge, or any machine capable of executing a set of instructions (sequential or otherwise) that specify actions to be taken by that machine. Further, while only a single computing device is illustrated, the term “computing device” shall also be taken to include any collection of computing devices that individually or jointly execute a set (or multiple sets) of instructions to perform the methods discussed herein.

The example computing device 1200 may include a processing device (e.g., a general-purpose processor, a PLD, etc.) 1202, a main memory 1204 (e.g., synchronous dynamic random-access memory (DRAM), read-only memory (ROM)), a static memory 1206 (e.g., flash memory and a data storage device 1218), which may communicate with each other via a bus 1230.

Processing device 1202 may be provided by one or more general-purpose processing devices such as a microprocessor, central processing unit, or the like. In an illustrative example, processing device 1202 may include a complex instruction set computing (CISC) microprocessor, reduced instruction set computing (RISC) microprocessor, very long instruction word (VLIW) microprocessor, or a processor implementing other instruction sets or processors implementing a combination of instruction sets. Processing device 1202 may also include one or more special-purpose processing devices such as an application specific integrated circuit (ASIC), a field programmable gate array (FPGA), a digital signal processor (DSP), network processor, or the like. The processing device 1202 may be configured to execute the operations described herein, in accordance with one or more aspects of the present disclosure, for performing the operations and steps discussed herein.

Computing device 1200 may further include a network interface device 1208 which may communicate with a communication network 1220. The computing device 1200 also may include a video display unit 1210 (e.g., a liquid crystal display (LCD) or a cathode ray tube (CRT)), an alphanumeric input device 1212 (e.g., a keyboard), a cursor control device 1214 (e.g., a mouse) and an acoustic signal generation device 1216 (e.g., a speaker). In one embodiment, video display unit 1210, alphanumeric input device 1212, and cursor control device 1214 may be combined into a single component or device (e.g., an LCD touch screen).

Data storage device 1218 may include a computer-readable storage medium 1228 on which may be stored one or more sets of instructions 1225 that may include instructions for one or more components/programs/applications 1242 for carrying out the operations (e.g., operations of method 1200 in FIG. 12) described herein, in accordance with one or more aspects of the present disclosure. Instructions 1225 may also reside, completely or at least partially, within main memory 1204 and/or within processing device 1202 during execution thereof by computing device 1200, main memory 1204 and processing device 1202 also constituting computer-readable media. The instructions 1225 may further be transmitted or received over a communication network 1220 via network interface device 1208.

While computer-readable storage medium 1228 is shown in an illustrative example to be a single medium, the term “computer-readable storage medium” should be taken to include a single medium or multiple media (e.g., a centralized or distributed database and/or associated caches and servers) that store the one or more sets of instructions. The term “computer-readable storage medium” shall also be taken to include any medium that is capable of storing, encoding or carrying a set of instructions for execution by the machine and that cause the machine to perform the methods described herein. The term “computer-readable storage medium” shall accordingly be taken to include, but not be limited to, solid-state memories, optical media and magnetic media.

In the above description, some portions of the detailed description are presented in terms of algorithms and symbolic representations of operations on analog signals and/or digital signals or data bits within a non-transitory storage medium. These algorithmic descriptions and representations are the means used by those skilled in the data processing arts to most effectively convey the substance of their work to others skilled in the art. An algorithm is here and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared and otherwise manipulated. It has proven convenient at times, principally for reasons of common usage, to refer to these signals as bits, values, elements, symbols, characters, terms, numbers, or the like.

Reference in the description to “an embodiment,” “one embodiment,” “an example embodiment,” “some embodiments,” and “various embodiments” means that a particular feature, structure, step, operation, or characteristic described in connection with the embodiment(s) is included in at least one embodiment of the disclosure. Further, the appearances of the phrases “an embodiment,” “one embodiment,” “an example embodiment,” “some embodiments,” and “various embodiments” in various places in the description do not necessarily all refer to the same embodiment(s).

The description includes references to the accompanying drawings, which form a part of the detailed description. The drawings show illustrations in accordance with exemplary embodiments. These embodiments, which may also be referred to herein as “examples,” are described in enough detail to enable those skilled in the art to practice the embodiments of the claimed subject matter described herein. The embodiments may be combined, other embodiments may be utilized, or structural, logical, and electrical changes may be made without departing from the scope and spirit of the claimed subject matter. The embodiments described herein are not intended to limit the scope of the subject matter but rather to enable one skilled in the art to practice, make, and/or use the subject matter.

It should be borne in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as “forming,” “configuring,” “coupling,” “providing,” “selecting,” or the like, refer to the actions and processes of an integrated circuit (IC) controller, or similar electronic device, that manipulates and transforms data represented as physical (e.g., electronic) quantities within the controller's registers and memories into other data similarly represented as physical quantities within the controller memories or registers or other such information non-transitory storage medium.

The words “example” or “exemplary” are used herein to mean serving as an example, instance, or illustration. Any aspect or design described herein as “example” or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or.” That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Moreover, use of the term “an embodiment” or “one embodiment” or “an embodiment” or “one embodiment” throughout is not intended to mean the same embodiment or embodiment unless described as such.

Embodiments described herein may also relate to an apparatus (e.g., such as an AC-DC converter, and/or an ESD protection system/circuit) for performing the operations herein. This apparatus may be specially constructed for the required purposes, or it may include firmware or hardware logic selectively activated or reconfigured by the apparatus. Such firmware may be stored in a non-transitory computer-readable storage medium, such as, but not limited to, read-only memories (ROMs), random access memories (RAMs), EPROMs, EEPROMs, flash memory, or any type of media suitable for storing electronic instructions. The term “computer-readable storage medium” should be taken to include a single medium or multiple media that store one or more sets of instructions. The term “computer-readable medium” shall also be taken to include any medium that is capable of storing, encoding, or carrying a set of instructions for execution by the machine and that causes the machine to perform any one or more of the methodologies of the present embodiments. The term “computer-readable storage medium” shall accordingly be taken to include, but not be limited to, solid-state memories, optical media, magnetic media, any medium that is capable of storing a set of instructions for execution by the machine and that causes the machine to perform any one or more of the methodologies of the present embodiments.

The above description sets forth numerous specific details such as examples of specific systems, components, methods, and so forth, to provide a good understanding of several embodiments of the present disclosure. It is to be understood that the above description is intended to be illustrative and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A signal routing system comprising:
a first uniform conductive region electrically coupled to a first electronic component associated with a first impedance;
a second uniform conductive region electrically coupled to a second electronic component associated with a second impedance; and
a non-uniform conductive region disposed between the first uniform conductive region and the second uniform conductive region, the non-uniform conductive region having a geometry that varies along a longitudinal direction to form a taper that is configured to produce a spatially varying characteristic impedance along the non-uniform conductive region.

2. The signal routing system of claim 1, further comprising:
a via electrically coupled to the second uniform conductive region; and
a third uniform conductive region electrically coupled between the via and the second electronic component.

3. The signal routing system of claim 2, wherein the third uniform conductive region is configured to maintain the second impedance.

4. The signal routing system of claim 2, further comprising:
a fourth uniform conductive region electrically coupled the second electronic component; and
a second non-uniform conductive region disposed between the third uniform conductive region and the fourth uniform conductive region, the second non-uniform conductive region having a second geometry that varies along the longitudinal direction to form a taper that is configured to produce a spatially varying characteristic impedance along the non-uniform conductive region.

5. The signal routing system of claim 1, further comprising:
a bending conductive region electrically coupled to the second uniform conductive region, wherein the bending conductive region varies along a transverse direction; and
a third uniform conductive region electrically coupled between the bending conductive region and the second electronic component.

6. The signal routing system of claim 1, wherein the non-uniform conductive region varies along a transverse direction to form a bending conductive region.

7. The signal routing system of claim 1, further comprising:
a third uniform conductive region electrically coupled to the second electronic component; and
a plurality of additional non-uniform conductive regions disposed between the non-uniform conductive region and the third uniform conductive region.

8. The signal routing system of claim 1, wherein the first electronic component is configured to transmit a signal across the first uniform conductive region, and the non-uniform conductive region has a taper length selected based on a data rate of the signal, such that a longer taper length provides a lower cut-off frequency and improved return loss over a broader frequency range.

9. The signal routing system of claim 8, wherein the taper length is between 0.2 inch and 1.5 inches for a printed circuit board routing, corresponding to a cut-off frequency range of approximately 0.2 gigahertz to 5 gigahertz.

10. The signal routing system of claim 1, wherein the taper has a slope between 0.08 degree and 0.7 degree for a printed circuit board routing, and between 0.05 degree and 0.5 degree for a package substrate routing, the slope being determined by a ratio of trace width change to taper length.

11. A method comprising:
providing a first uniform conductive region electrically coupled to a first electronic component associated with a first impedance;
providing a second uniform conductive region electrically coupled to a second electronic component associated with a second impedance; and
forming a non-uniform conductive region between the first uniform conductive region and the second uniform conductive region, the non-uniform conductive region having a geometry that varies along a longitudinal direction to form a taper that is configured to produce a spatially varying characteristic impedance along the non-uniform conductive region.

12. The method of claim 11, further comprising:
electrically coupling a via to the second uniform conductive region; and
forming a third uniform conductive region electrically coupled between the via and the second electronic component.

13. The method of claim 12, further comprising configuring the third uniform conductive region to maintain the second impedance.

14. The method of claim 12, further comprising:
forming a fourth uniform conductive region electrically coupled to the second electronic component; and
forming a second non-uniform conductive region between the third uniform conductive region and the fourth uniform conductive region, the second non-uniform conductive region having a second geometry that varies along a longitudinal direction to form a taper that is configured to produce a spatially varying characteristic impedance along the second non-uniform conductive region.

15. The method of claim 11, further comprising:
forming a bending conductive region electrically coupled to the second uniform conductive region, wherein the bending conductive region varies along a transverse direction; and
forming a third uniform conductive region electrically coupled between the bending conductive region and the second electronic component.

16. The method of claim 11, further comprising forming the non-uniform conductive region to vary along a transverse direction to form a bending conductive region.

17. The method of claim 11, further comprising:
forming a third uniform conductive region electrically coupled to the second electronic component; and
forming a plurality of additional non-uniform conductive regions disposed between the non-uniform conductive region and the third uniform conductive region.

18. The method of claim 11, further comprising:
configuring the first electronic component to transmit a signal across the first uniform conductive region; and
selecting a taper length of the non-uniform conductive region based on a data rate of the signal, such that a longer taper length provides a lower cut-off frequency and improved return loss over a broader frequency range,
wherein the taper length is between 0.2 inch and 1.5 inches for a printed circuit board routing, corresponding to a cut-off frequency range of approximately 0.2 gigahertz to 5 gigahertz.

19. The method of claim 11, further comprising forming the taper with a slope between 0.08 degree and 0.7 degree for a printed circuit board routing, and between 0.05 degree and 0.5 degree for a package substrate routing, the slope being determined by a ratio of trace width change to taper length.

20. A high-speed electronic system comprising:
a transmitter associated with a first impedance;
a receiver associated with a second impedance;
a first uniform conductive region electrically coupled to the transmitter;
a second uniform conductive region electrically coupled to the receiver; and
a non-uniform conductive region disposed between the first uniform conductive region and the second uniform conductive region, the non-uniform conductive region having a geometry that varies along a longitudinal direction to form a taper.
